(19) United States
(12) Patent Application Publication
(10) Pub. No.: US 2026/0201551 A1
(43) Pub. Date: Jul. 16, 2026

(54) CLEAN METHOD FOR DEPOSITION CHAMBERS

(71) Applicant: Skytech Inc., Hsinchu County (TW)

(72) Inventors: TA-HAO KUO, Hsinchu County (TW); WEI-DER SUNG, Hsinchu County (TW); YU-CHI LIU, Hsinchu County (TW); CHUN-FU WANG, Hsinchu County (TW)

(21) Appl. No.: 19/216,649

(22) Filed: May 22, 2025

(30) Foreign Application Priority Data
Jan. 13, 2025 (TW) 114101370

(51) Int. Cl. C23C 16/44; C23C 16/06; C23C 16/455

(52) U.S. Cl. CPC C23C 16/4405; C23C 16/06; C23C 16/4408; C23C 16/45553

(57) ABSTRACT

This disclosure is a cleaning method for a deposition chamber. First, a purge gas is supplied into a deposition chamber, and molybdenum precursor remaining in the deposition chamber is extracted through a vacuum pump. Then, a hydrogen plasma is used to reduce a molybdenum trioxide deposit attached to the inner surface of the deposition chamber, and the molybdenum trioxide deposit is reduced to molybdenum particles and water vapor. The purge gas is again supplied into the deposition chamber, and molybdenum particles and water vapor is extracted through the vacuum pump. Through the method described in this invention, the molybdenum trioxide deposit attached to the inner surface of the deposition chamber and the residual molybdenum precursor can be effectively removed, and the number of particles in the deposition chamber can be reduced to improve the quality and yield of the subsequent thin film deposition process.

### CROSS-REFERENCE TO RELATED APPLICATIONS

This non-provisional application claims priority claim under 35 U.S.C. §119(a) on Taiwan Patent Application No. 114101370 filed January 13, 2025, the entire contents of which are incorporated herein by reference.

### TECHNICAL FIELD

This disclosure is a cleaning method for a deposition chamber that effectively minimizes particulate contamination within the deposition chamber, leading to enhanced quality and yield in subsequent thin film deposition processes.

### BACKGROUND

Thin film deposition is a commonly used process technology in semiconductor manufacturing, mainly used to form thin films on the surface of substrates. For example, the film deposition comprises chemical vapor deposition (CVD), physical vapor deposition (PVD), and atomic layer deposition (ALD).

Taking atomic layer deposition (ALD) as an example, most ALD involves inputting one type of precursor gas into the deposition chamber at a time, allowing the precursor gas to react with the surface of the wafer. Subsequently, an inert gas is transported into the deposition chamber to thoroughly purge unreacted precursors and byproducts from within the chamber. Then, another type of precursor gas is introduced to react with the substance formed on the wafer surface in the previous step, forming a deposition of a single atomic layer. This cycle is repeated multiple times until the desired thin film thickness is achieved.

In the course of deposition, besides the intended thin film growth on the surface of the substrate, unwanted deposits also accumulate on the inner surfaces of the deposition chamber. With prolonged use, the thickness of these deposits on the inner surfaces of the deposition chamber progressively increases, and the structure of these deposits is rather fragile. These deposits may be metal oxide films, and they may detach from the inner surfaces of the deposition chamber and introduce contamination within the deposition chamber, such as the generation of particles. The presence of particles can result in non-uniformity in the deposited thin film thickness or elevate the impurity levels within the deposited thin film, consequently impacting the electrical or optical properties of subsequently fabricated electronic devices.

To address the aforementioned problems, the current industry practice before performing the deposition process is generally to introduce precursor gases or inert gases into the deposition chamber to remove particles within the deposition chamber. However, the above steps can only initially clean the interior space of the deposition chamber and remove particles located within the interior space, but cannot truly clean the deposition chamber. For example, it cannot remove deposits attached to the inner surfaces of the deposition chamber. If the deposits on the inner surfaces of the deposition chamber fall off during the deposition process, they will still contaminate the interior space of the deposition chamber and the substrate, thereby leading to uneven thickness or increased impurity content of the thin film deposited on the substrate surface.

### SUMMARY

In order to solve the problems described in the prior art, this invention provides a cleaning method for a deposition chamber, which can be used to remove deposits attached to the inner surfaces of the deposition chamber, so as to prevent the deposits from detaching from the inner surfaces of the deposition chamber and causing contamination to the interior space of the deposition chamber or the substrate.

It is an objective of this invention to provide a cleaning method for a deposition chamber, primarily involving the reduction of molybdenum trioxide adhered to the inner surfaces of the deposition chamber by a hydrogen plasma, transforming the molybdenum trioxide into a molybdenum deposit, molybdenum particles and water vapor. Following this, a purge gas is introduced into the deposition chamber, and a vacuum pump is used to exhaust residual molybdenum precursors, molybdenum particles and water vapor from within the deposition chamber.

The cleaning method for the deposition chamber according to this invention effectively eliminates molybdenum trioxide adhered to the inner surfaces of the deposition chamber, as well as particles and molybdenum precursors present within the deposition chamber. This leads to a substantial reduction in the number of particles inside the deposition chamber, advantageously enhancing the quality and yield of subsequent thin film deposition processes.

It is an objective of the invention to provide a cleaning method for a deposition chamber, specifically applicable to the cleaning of deposition chambers employed for molybdenum metal thin film deposition. The deposition chamber can be used to perform deposition processes on substrates inside, forming molybdenum metal thin films on the surface of the substrate, and removing the substrates after the deposition process is completed. Subsequently, the decision to clean the deposition chamber can be made based on the duration and frequency of thin film deposition runs performed within the deposition chamber, with the aim of maintaining the concentration of particles within the deposition chamber at a minimal level.

To achieve the foregoing objectives, this disclosure provides a cleaning method for a deposition chamber, comprising: introducing a purge gas into an interior space of a deposition chamber and evacuating gas within the interior space of the deposition chamber through a vacuum pump; reducing a deposit attached to an inner surface of the deposition chamber through a hydrogen plasma, wherein the deposit includes a molybdenum trioxide deposit; and introducing the purge gas into the interior space of the deposition chamber and evacuating the gas within the interior space of the deposition chamber through the vacuum pump.

This disclosure provides another cleaning method for a deposition chamber, comprising: introducing a purge gas into an interior space of a deposition chamber and evacuating gas within the interior space of the deposition chamber through a vacuum pump; reducing a molybdenum trioxide deposit attached to an inner surfaces of the deposition chamber through a hydrogen plasma, and reducing the molybdenum trioxide deposit into water vapor and a molybdenum structure, wherein the molybdenum structure includes molybdenum deposits located on the inner surfaces of the deposition chamber and molybdenum particles located within the interior space of the deposition chamber; and introducing the purge gas into the interior space of the deposition chamber and evacuating the molybdenum particles within the interior space of the deposition chamber through the vacuum pump.

The cleaning method for the deposition chamber according to this invention has the following advantages: it can effectively remove molybdenum trioxide attached to the inner surfaces of the deposition chamber, and remove molybdenum particles and molybdenum precursors inside the deposition chamber, which is beneficial for improving the quality and yield of subsequent thin film deposition.

### BRIEF DESCRIPTION OF THE DRAWINGS

FIG. 1 is a flowchart of a deposition and cleaning method according to an embodiment of the invention.

FIG. 2 is a flowchart of a cleaning method for a deposition chamber according to an embodiment of the invention.

### DETAILED DESCRIPTION

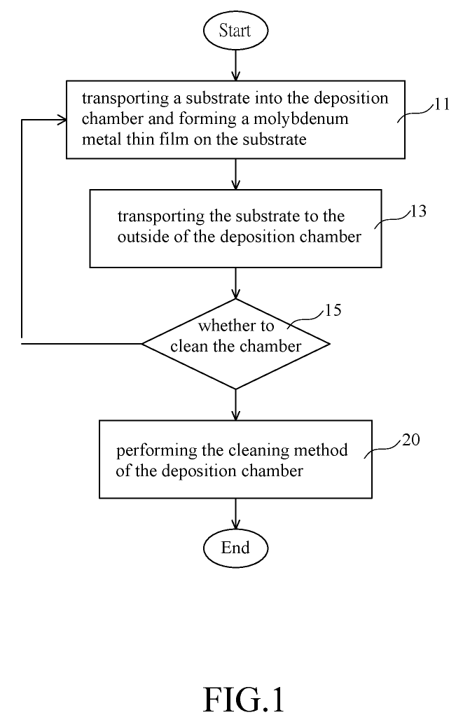

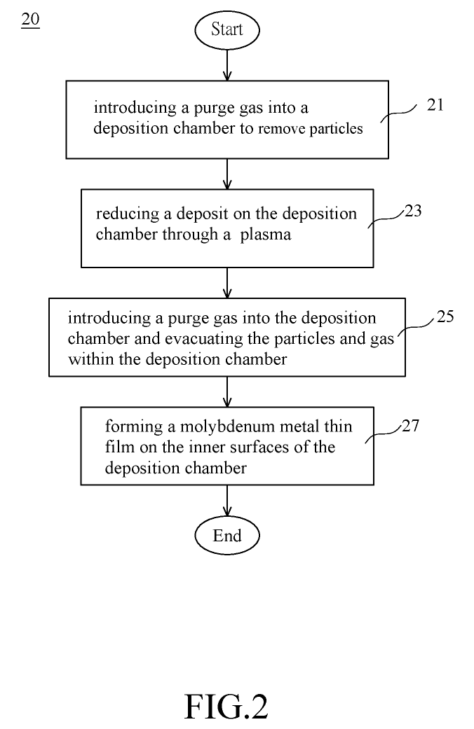

FIG. 1 is a flowchart of a deposition and cleaning method according to an embodiment of the invention. FIG. 2 is a flowchart of a cleaning method for a deposition chamber according to an embodiment of the invention. As shown in the figures, during a thin film deposition process, at least one substrate can be transported into a deposition chamber, and the thin film deposition process is performed on the substrate within an internal of the deposition chamber to form a metal thin film on the surface of the substrate, as shown in step 11.

Depending on the application field, the substrate described in this invention may be silicon, silicon dioxide, strained silicon, silicon-on-insulator (SOI), carbon-doped silicon oxide, amorphous silicon, doped silicon, germanium, gallium arsenide, glass, sapphire, and various other materials. For example, the substrate includes titanium nitride (TiN), titanium silicide (TiSi), tungsten-titanium silicide alloy, clean silicon (Si), boron-doped silicon germanium (SiGeB), clean silicon phosphide (SiP), etc.

In one embodiment of this invention, the deposition chamber may be chemical vapor deposition (CVD) chamber, a physical vapor deposition (PVD) chamber, or an atomic layer deposition (ALD) chamber. For the convenience of explanation, the subsequent description will focus on the example of depositing a molybdenum metal thin film on a surface of a substrate using the atomic layer deposition chamber.

When depositing a molybdenum metal thin film on the surface of the substrate using the atomic layer deposition, a molybdenum precursor is introduced into the deposition chamber. Examples of molybdenum precursors include molybdenum pentachloride (MoCl₅), molybdenum dichloride dioxide (MoO₂Cl₂), molybdenum tetrachloride oxide (MoOCl₄), molybdenum hexacarbonyl, bis(tert-butylimido)bis(dimethylamido)molybdenum, or bis(ethylbenzene)molybdenum.

In one embodiment of the invention, molybdenum dichloride dioxide (MoO₂Cl₂) can be used in conjunction with hydrogen plasma to deposit the molybdenum metal thin film on the surface of the substrate. For example, molybdenum dichloride dioxide and hydrogen plasma can be sequentially delivered to the substrate surface, and after multiple cycles, the molybdenum metal thin film of a desired thickness can be gradually grown on the surface of the substrate, as illustrated by the following reaction formula: MoO₂Cl₂+H₂ (Plasma)→Mo (solid)+HCL (gas) +H₂O (gas)

Following this, the substrate having the molybdenum metal thin film formed thereon after the deposition process can be taken out of the deposition chamber, as shown in step 13.

During the deposition process, a portion of the molybdenum dichloride dioxide (MoO₂Cl₂) precursor may not fully react, leaving residues within the deposition chamber or on its inner surfaces. This residual precursor may gradually lead to the formation of a molybdenum trioxide (MoO₃) deposit on the inner surfaces of the deposition chamber. The molybdenum trioxide deposit has a fragile structure and exhibits poor adhesion to the inner surfaces of the deposition chamber. Consequently, this molybdenum trioxide deposit may detach from the inner surfaces, generating particles within the deposition chamber. For instance, the particle count inside the deposition chamber may exceed 10,000. An excessive number of these particles can introduce defects into the molybdenum metal thin film being deposited on the surface of the substrate and diminish the yield of the thin film process, potentially resulting in wafer defects.

In order to decrease the particle count and mitigate their adverse effects on the deposited thin film on the substrate surface, a purge gas is commonly introduced into the deposition chamber prior to the deposition step, and in conjunction with a vacuum pump, the gas and particles within the interior space of the deposition chamber are extracted to remove suspended particles.

Following the completion of the aforementioned cleaning steps, a new substrate can be introduced into the interior space of the deposition chamber, and subsequently, the metal thin film can be deposited onto the surface of the substrate.

However, in actual implementation, the purge gas is limited to removing only suspended particles within the interior space of the deposition chamber and is ineffective at removing deposits adhered to the inner surfaces of the deposition chamber. Consequently, after the flow of purge gas into the interior space of the deposition chamber is terminated, if loosely bound deposits detach from the inner surface, they will still generate particles within the deposition chamber, negatively impacting the quality of the thin film subsequently deposited on the surface of the substrate and potentially leading to defects on the wafer surface.

To address the aforementioned issues, this invention introduces an innovative cleaning method for a deposition chamber, which includes an additional step of determining whether cleaning of the deposition chamber is required, as shown in step 15.

Specifically, the necessity for cleaning the deposition chamber may be determined based on the number of thin film deposition cycles or the cumulative deposition time. For instance, a predetermined value can be calculated based on the correlation between the accumulated number of deposition cycles and the presence of particles within the deposition chamber or deposits on the surfaces of the deposition chamber.

If the number of thin film deposition cycles or the cumulative deposition time of the deposition chamber is below the predetermined value, it signifies that the deposition chamber can continue to deposit thin films on substrates and execute step 11 to step 13.

Conversely, if the number of thin film deposition cycles or the cumulative deposition time of the deposition chamber exceeds the predetermined value, it signifies that a certain thickness of deposits, such as a molybdenum trioxide deposit, has accumulated on the inner surfaces of the deposition chamber, necessitating a deposition chamber cleaning step and the execution of step 20 to implement the cleaning method of the deposition chamber. In alternative embodiments, the number of particles within the deposition chamber may be directly measured, and when this number surpasses a threshold value, it indicates the need for deposition chamber cleaning and the execution of step 20.

The detailed cleaning method of the deposition chamber is shown in FIG. 2. Initially, a purge gas is introduced into the interior space of the deposition chamber, and subsequently, a vacuum pump is employed to evacuate the gas from the deposition chamber, thereby removing suspended particles and molybdenum precursors, as indicated in step 21.

In practice, the purge gas may be an inert gas or a gas that does not interfere with subsequent deposition processes, such as argon or nitrogen. When the deposition chamber is the atomic layer deposition (ALD) chamber used for depositing molybdenum metal thin films on the surface of the substrate, the particles within the deposition chamber may consist of molybdenum trioxide particles or molybdenum precursors. For example, molybdenum precursors may includes molybdenum pentachloride (MoCl₅), molybdenum dichloride dioxide (MoO₂Cl₂), molybdenum tetrachloride oxide (MoOCl₄), molybdenum hexacarbonyl, bis(tert-butylimido)bis(dimethylamido)molybdenum, or bis(ethylbenzene)molybdenum.

Following this, the deposits on the inner surfaces of the deposition chamber are reduced via plasma treatment, as shown in step 23. In one embodiment of the invention, the deposits on the inner surfaces of the deposition chamber may be a molybdenum trioxide (MoO₃) deposit, which can be reduced using hydrogen plasma according to the following reaction: 2MoO₃_{} (solid)+H₂ (Plasma)→2Mo (solid)+2H₂O(gas)

Specifically, the hydrogen plasma interacts with the molybdenum trioxide deposit adhered to the inner surfaces of the deposition chamber, causing its reduction into molybdenum and water vapor. For instance, the resulting molybdenum may either attach to the inner surfaces of the deposition chamber, forming a molybdenum deposit, or detach and fall within the deposition chamber, forming molybdenum particles.

In actual implementation, the hydrogen plasma may be generated using a remote plasma source, a capacitively coupled plasma (CCP) source, an inductively coupled plasma (ICP) source, or a microwave plasma source.

During the removal of deposits adhered to the inner surfaces of the deposition chamber using hydrogen plasma, the purge gas can be introduced into the deposition chamber, and the vacuum pump employed to evacuate contaminants and gases, thereby initially removing pollutants from the deposition chamber. For instance, remote hydrogen plasma may be directed into the deposition chamber, or hydrogen plasma may be generated within the deposition chamber. After cleaning the deposition chamber with hydrogen plasma for a predetermined duration, the purge gas is introduced, and the vacuum pump is used to exhaust particles, pollutants, and/or gases from the deposition chamber. These steps can be performed in multiple cycles.

Following the removal of deposits from the inner surfaces of the deposition chamber via hydrogen plasma treatment, the purge gas may be introduced into the deposition chamber, and subsequently, the vacuum pump may be employed to evacuate the gas from the deposition chamber, thereby removing suspended particles and water vapor. For instance, the particles may include molybdenum particles and molybdenum precursors, as shown in step 25.

The aforementioned step 21 to step 25 may be iterated to remove the majority of the molybdenum trioxide deposit adhered to the inner surfaces of the deposition chamber. In actual implementation, the number of repetitions for step 21 to step 25 can be defined, for instance, this number can be calculated based on the operational time of the deposition chamber or the number of deposition cycles performed.

In another embodiment of the invention, the number of repetitions for step 21, step 23, and step 25 may be predetermined prior to cleaning the deposition chamber. Specifically, the number of cycles for introducing purge gas into and evacuating gas from the deposition chamber using the vacuum pump can be set to remove suspended particles. For instance, after repeated execution of step 21 to step 25, the particle count within the deposition chamber may be reduced to below 300, demonstrating that the cleaning method of the deposition chamber of the invention can effectively control the particle concentration within the deposition chamber and enhance the quality of the molybdenum metal thin film deposited on the surface of the substrate.

After removing the molybdenum trioxide deposit attached to the inner surfaces of the deposition chamber and removing the particles inside the deposition chamber, a molybdenum metal thin film can be further formed on the inner surfaces of the deposition chamber. For example, when the substrate is not transported into the deposition chamber, the molybdenum metal thin film can be deposited on the inner surfaces of the deposition chamber using molybdenum dichloride dioxide (MoO₂Cl₂) in conjunction with hydrogen plasma. The structure of the molybdenum metal thin film deposited on the inner surfaces of the deposition chamber is denser than that of molybdenum oxide and has higher adhesion to the inner surfaces of the deposition chamber, making it less likely to fall off from the inner surfaces of the deposition chamber.

In addition, the molybdenum metal thin film formed on the inner surfaces of the deposition chamber can be used to cover the deposits remaining on the inner surfaces of the deposition chamber, so as to prevent the incompletely removed deposits from falling off the inner surfaces of the deposition chamber and contaminating the interior space of the deposition chamber.

Specifically, a molybdenum structure resulting from the hydrogen plasma reduction of the molybdenum trioxide deposit can exist as either a molybdenum deposit adhered to the inner surfaces of the deposition chamber or as molybdenum particles suspended within the deposition chamber. While the vacuum pump can evacuate the molybdenum particles from the interior space of the deposition chamber, it cannot remove the molybdenum deposit attached to the inner walls. Consequently, even after the aforementioned cleaning steps, the molybdenum deposit on the inner surfaces may still detach and fall into the deposition chamber, generating molybdenum particles and contaminating both the deposition chamber and the substrate. By forming the molybdenum metal thin film on the inner surfaces of the deposition chamber, the residual molybdenum deposit can be encapsulated, thus preventing their detachment and the subsequent formation of molybdenum particles within the deposition chamber.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A cleaning method for a deposition chamber, comprising:
introducing a purge gas into an interior space of a deposition chamber and evacuating gas within the interior space of the deposition chamber through a vacuum pump;
reducing a deposit attached to an inner surface of the deposition chamber through a hydrogen plasma, wherein the deposit includes a molybdenum trioxide deposit; and
introducing the purge gas into the interior space of the deposition chamber and evacuating the gas within the interior space of the deposition chamber through the vacuum pump.

2. The cleaning method as claim 1, further comprising: forming a molybdenum metal thin film on the inner surfaces of the deposition chamber.

3. The cleaning method as claim 1, wherein the hydrogen plasma reacts with the molybdenum trioxide deposit on the inner surfaces of the deposition chamber and generates molybdenum and water vapor.

4. The cleaning method as claim 1, wherein the hydrogen plasma reacts with the molybdenum trioxide deposit on the inner surfaces of the deposition chamber and generates molybdenum particles and water vapor, and when the hydrogen plasma reduces the molybdenum trioxide deposit attached to the inner surfaces of the deposition chamber, the purge gas is introduced into the interior space of the deposition chamber, and the molybdenum particles and water vapor within the interior space of the deposition chamber are evacuated through the vacuum pump.

5. The cleaning method as claim 1, wherein the hydrogen plasma is generated by a remote plasma source, a capacitively coupled plasma source, an inductively coupled plasma source, or a microwave plasma source.

6. The cleaning method as claim 1, wherein the vacuum pump is used to evacuate the gas and molybdenum precursors within the interior space of the deposition chamber, and the molybdenum precursors include molybdenum pentachloride, molybdenum dichloride dioxide, molybdenum tetrachloride oxide, molybdenum hexacarbonyl, bis(tert-butylimido)bis(dimethylamido)molybdenum, or bis(ethylbenzene)molybdenum.

7. The cleaning method as claim 1, further comprising:
transporting a substrate into the interior space of the deposition chamber and forming a molybdenum metal thin film on a surface of the substrate;
transporting the substrate to the outside of the deposition chamber; and
determining whether to clean the deposition chamber.

8. The cleaning method as claim 7, further comprising: determining whether to clean the deposition chamber based on usage time or number of depositions of the deposition chamber.

9. A cleaning method for a deposition chamber, comprising:
introducing a purge gas into an interior space of a deposition chamber and evacuating gas within the interior space of the deposition chamber through a vacuum pump;
reducing a molybdenum trioxide deposit attached to an inner surfaces of the deposition chamber through a hydrogen plasma, and reducing the molybdenum trioxide deposit into water vapor and a molybdenum structure, wherein the molybdenum structure includes molybdenum deposits located on the inner surfaces of the deposition chamber and molybdenum particles located within the interior space of the deposition chamber; and
introducing the purge gas into the interior space of the deposition chamber and evacuating the molybdenum particles within the interior space of the deposition chamber through the vacuum pump.

10. The cleaning method as claim 9, further comprising: forming a molybdenum metal thin film on the inner surfaces of the deposition chamber, and using the molybdenum metal thin film to cover the molybdenum deposits attached to the inner surfaces of the deposition chamber.

11. The cleaning method as claim 9, wherein the hydrogen plasma is generated by a remote plasma source, a capacitively coupled plasma source, an inductively coupled plasma source, or a microwave plasma source.

12. The cleaning method as claim 9, wherein the vacuum pump is used to evacuate the gas and molybdenum precursors within the interior space of the deposition chamber, and the molybdenum precursors include molybdenum pentachloride, molybdenum dichloride dioxide, molybdenum tetrachloride oxide, molybdenum hexacarbonyl, bis(tert-butylimido)bis(dimethylamido)molybdenum, or bis(ethylbenzene)molybdenum.

13. The cleaning method as claim 9, further comprising:
transporting a substrate into the interior space of the deposition chamber and forming a molybdenum metal thin film on a surface of the substrate;
transporting the substrate to the outside of the deposition chamber; and
determining whether to clean the deposition chamber.

14. The cleaning method as claim 13, further comprising: determining whether to clean the deposition chamber based on usage time or number of depositions of the deposition chamber.
